(19) United States
(12) Patent Application Publication
(10) Pub. No.: US 2026/0262345 A1
(43) Pub. Date: Sep. 3, 2026

(54) OPTOELECTRONIC SEMICONDUCTOR CHIP HAVING A REFLECTIVE LAYER SYSTEM

(71) Applicant: AMS-OSRAM INTERNATIONAL GMBH, Regensburg (DE)

(72) Inventors: Walter PETER, Hemau (DE); Michael HUBER, Bad Abbach (DE); Sebastian ALARCON VILLASECA, Regensburg (DE); Christopher WIESMANN, Barbing (DE); Robert WALTER, Parsberg (DE)

(21) Appl. No.: 19/163,412

(22) PCT Filed: Mar. 1, 2024
(86) PCT No.: PCT/EP2024/055462

§ 371 Date: Sep. 9, 2025

(30) Foreign Application Priority Data
Mar. 15, 2023 (DE) 10 2023 106 511.4

(51) Int. Cl. H10H 20/841; H10H 20/825

(52) U.S. Cl. CPC H10H 20/841; H10H 20/825

(57) ABSTRACT

An optoelectronic semiconductor chip and a corresponding production method are provided. The semiconductor chip includes a semiconductor layer sequence for emitting electromagnetic radiation, and a reflective layer system. The layer system includes a mirror which is reflective for the electromagnetic radiation, and a metal layer which is reflective for the electromagnetic radiation and also an adhesion enhancing layer. The adhesion enhancing layer is arranged between the mirror and the metal layer.

### CROSS-REFERENCE TO RELATED APPLICATIONS

This application is a national phase of International Application No. PCT/EP 2024/055462 filed on Mar. 1, 2024, which claims priority to German patent application DE 10 2023 106 511.4, which was filed on Mar. 15, 2023, the entire contents of both of which are incorporated herein by reference.

### TECHNICAL BACKGROUND OF INVENTION

The invention relates to an optoelectronic semiconductor chip for emitting electromagnetic radiation having a reflective layer system.

### BACKGROUND

It is known to equip optoelectronic semiconductor chips for emitting electromagnetic radiation, in particular light-emit-ting diodes, also called LEDs, with reflective layer systems. The outcoupling efficiency can be improved as a result. The reflective layer system can comprise a metal reflector or can comprise a Bragg mirror.

DE 10 2009 019 524 A1 discloses an optoelectronic semiconductor chip having a reflective metal layer and an adhesion enhancing layer between metal layer and active layer system. Moreover, DE 10 2009 019 524 A1 discloses an optoelectronic semiconductor chip having a Bragg mirror, wherein one layer of each layer pair consists of an adhesion enhancing material.

### SUMMARY

It is an object of the invention to specify an optoelectronic semiconductor chip for emitting electromagnetic radiation which is particularly efficient and at the same time is of robust construction. The object is achieved by the semiconductor chip and also the associated production method having the features of the independent claims. The claims dependent thereon specify preferred configurations.

In accordance with one embodiment, an optoelectronic semiconductor chip comprises a semiconductor layer sequence and a reflective layer system. The semiconductor layer sequence comprises a first semiconductor layer of a first conductivity type, a second semiconductor layer of a second conductivity type and, arranged therebetween, an active region for emitting electro-magnetic radiation.

The reflective layer system comprises a metal layer which is reflective for the electromagnetic radiation. Moreover, the layer system comprises an adhesion enhancing layer, which e.g. can be arranged between the metal layer and the semiconductor layer sequence and consists of a different material than the metal layer. In accordance with one embodiment, the reflective layer system additionally comprises a mirror, wherein the adhesion enhancing layer is arranged between the mirror and the reflective metal layer.

A dielectric layer can be arranged between the adhesion enhancing layer and the active region. The dielectric layer can form the mirror. It can comprise or consist of aluminum oxide (in particular Al₂O₃), for example. The adhesion enhancing layer can directly adjoin the dielectric layer.

In accordance with one embodiment, the mirror comprises or is a Bragg mirror which is reflective for the electromagnetic radiation and which has alternating first layers and second layers, wherein the first layers have a different refractive index than the second layers. In this case, the adhesion enhancing layer is arranged between the Bragg mirror and the metal layer and consists of a different material than the first layers and the second layers and the metal layer.

Combining a mirror, in particular a Bragg reflector, with a reflective metal layer makes it possible to attain a particularly high reflectivity of the mirror system. In particular, the mirror may regionally have a reflectivity reduced by disturbances. In these disturbed regions, a reflectivity does not fall to zero, but rather is only somewhat reduced, since the metal layer reflects. It has additionally been found that the adhesion enhancing layer between the mirror and metal layer makes it possible to attain a high stability of the chip (which without this layer is very fragile).

In accordance with one embodiment, the optoelectronic semiconductor chip comprises a layer sequence comprising the semiconductor layer sequence and the reflective layer system.

The adhesion enhancing layer preferably comprises a material which is transparent to the electromagnetic radiation, or comprises the material to the extent of at least 60 or 90 percent by weight, or consists thereof. In particular, the transparent material can be a transparent conductive oxide, in particular zinc oxide. It is clear to a person skilled in the art that the term “consists (there) of” also encompasses a pure substance exhibiting method-typical impurities. A particularly high efficiency of the optoelectronic semiconductor chip can be attained with zinc oxide.

In accordance with one embodiment, the adhesion enhancing layer has a thickness of greater than or equal to 0.5 nm. In this case, it can have a thickness of less than or equal to 5 nm. Particularly preferably, it has a thickness of greater than or equal to 1 nm and less than or equal to 3 nm.

It has been found that these thicknesses make it possible to attain a particularly high efficiency of the optoelectronic semiconductor chip, especially if the adhesion enhancing layer comprises or consists of zinc oxide.

The first layers of the Bragg mirror can comprise or consist of SiO₂, for example, or the second layers can comprise or consist of Nb₂O₅, for example.

The reflective metal layer can preferably comprise silver, or it comprises silver to the extent of at least 60 or 90 percent by weight, or it consists thereof. It is likewise possible that it comprises gold, or it comprises gold to the extent of at least 60 or 90 percent by weight, or it consists of gold. It is likewise possible that it comprises aluminum, or it comprises aluminum to the extent of at least 60 or 90 percent by weight, or it consists of aluminum. A particularly good adhesion enhancement is attained if the metal layer comprises or consists of silver and the adhesion enhancing layer comprises or consists of zinc oxide, and the adhesion enhancing layer and the metal layer directly adjoin one another.

In accordance with one embodiment, the adhesion enhancing layer directly adjoins the metal layer.

A dielectric layer can be arranged between the adhesion enhancing layer and the Bragg mirror. Said dielectric layer can comprise for example aluminum oxide (in particular Al₂O₃), e.g. 60 or 90 percent by weight, or it consists thereof. The dielectric layer can serve for example as an encapsulation layer in order to protect the layers of the Bragg mirror. Accordingly, in addition to the dielectric layer, a further dielectric layer can also be arranged on the opposite side of the Bragg mirror with respect to the dielectric layer, in order to protect the Bragg mirror from both sides.

In accordance with one embodiment, the adhesion enhancing layer directly adjoins the dielectric layer.

In this case, a particularly good adhesion enhancement is attained if the metal layer comprises or consists of silver and the adhesion enhancing layer comprises or consists of zinc oxide, and the dielectric layer comprises or consists of aluminum oxide, and the metal layer, the adhesion enhancing layer and the dielectric layer directly adjoin one another.

In accordance with one embodiment, the dielectric layer directly adjoins one of the first layers or of the second layers. Accordingly, in this embodiment, in particular there is no further layer between the dielectric layer and one of the first or of the second layers.

In accordance with one embodiment, the optoelectronic semiconductor chip furthermore comprises a plurality of first contacting cutouts extending through the Bragg mirror. Moreover, the semiconductor chip in accordance with this embodiment comprises a first electrically conductive current impressing element arranged on a side of the reflective layer system facing away from the semiconductor layer sequence. Said current impressing element extends into the contacting cutouts such that there is a first electrically conductive connection between the first semiconductor layer and the first current impressing element. The first electrically conductive connection additionally extends via the first current impressing element along the contacting cutouts.

By means of the first current impressing element, a current can accordingly be impressed into the first semiconductor layer in order to energize the active region.

In accordance with one embodiment, the first current impressing element comprises a current impressing layer and also first contacting fingers monolithically connected to the current impressing layer, which extend into the first contacting cutouts, such that the first electrically conductive connection extends along the first contacting cutouts via the first contacting fingers.

In accordance with one embodiment, the semiconductor chip furthermore comprises an electrically conductive current distribution layer, which is arranged between the semiconductor layer sequence and the reflective layer system and is transparent to the electromagnetic radiation. In this case, the first electrically conductive connection extends through the transparent current distribution layer. The current distribution layer can in particular comprise or consist of a transparent metal oxide, e.g. indium tin oxide.

As mentioned above, the first electrically conductive connection extends along the first contacting cutouts. The layers of the Bragg mirror are arranged outside the contacting cutouts, as viewed laterally, with no or at least no significant current flow taking place through said layers. This may result in a laterally inhomogeneous energization of the first semiconductor layer. The energization of the first semiconductor layer can be laterally homogenized by means of the current distribution layer.

Preferably, the first electrically conductive connection extends through the adhesion enhancing layer and the metal layer.

In particular, in the first contacting cutouts the adhesion enhancing layer and the metal layer may extend between the current impressing element and the first semiconductor layer, and the electrically conductive connection may extend through the adhesion promoting layer) and the metal layer.

This configuration results in a significant improvement in the efficiency of the optoelectronic semiconductor chip in conjunction with good mechanical stability. The Bragg mirror is not present within the first contacting cutouts because the first contacting cutouts extend through the Bragg mirror. By virtue of the reflective metal layer, a high reflectivity is nevertheless attained within the first contacting cutouts. In this case, the adhesion enhancing layer simultaneously ensures that the semiconductor chip is mechanically stabilized.

In accordance with one embodiment, the optoelectronic semiconductor chip furthermore comprises at least one second contacting cutout extending through the Bragg mirror and the first semi-conductor layer, and also a second electrically conductive current impressing element. The second current impressing element extends into the second contacting cutout such that there is a second electrically conductive connection between the second semiconductor layer and the second current impressing element, and said second electrically conductive connection extends via the second current impressing element along the second contacting cutouts.

By means of the second current impressing element, a current can accordingly be impressed into the second semiconductor layer in order to energize the active region.

During the production of the optoelectronic semiconductor chip, the adhesion enhancing layer can be applied by means of cathode sputtering.

A method for producing the optoelectronic semiconductor chip comprises the step (S1) of producing the semiconductor layer sequence, e. g. by means of MOCVD (metal organic chemical vapor deposition) on a growth substrate, which is removed later, and the step of producing the reflective layer system. When producing the reflective layer system, firstly the mirror, e.g. the Bragg mirror, is produced (S2), e.g. by means of physical or chemical vapor deposition. Afterward, the adhesion enhancing layer is applied (S3) to the mirror, preferably by means of sputtering, also called “sputtering deposition”, and then the metal layer is applied (S4) to the adhesion enhancing layer, e.g. by means of physical vapor deposition.

In accordance with at least one embodiment, the method additionally comprises producing the first and/or second contacting cut-outs, e.g. by means of an etching process, and producing the respective current impressing elements.

### BRIEF DESCRIPTION OF THE FIGURES

Further advantages and advantageous configurations and developments of the optoelectronic semiconductor chip will become ap-parent from the following exemplary embodiments described in association with the schematic figures. In the figures:

FIG. 1: shows an optoelectronic semiconductor chip in accordance with one embodiment in a sectional illustration,

FIG. 2: shows the optoelectronic semiconductor chip in accordance with the embodiment in a plan view,

FIG. 3: shows the efficiency of the optoelectronic semiconductor chip in accordance with the embodiment for various layer thicknesses of the adhesion enhancing layer.

### DETAILED DESCRIPTION OF THE FIGURES

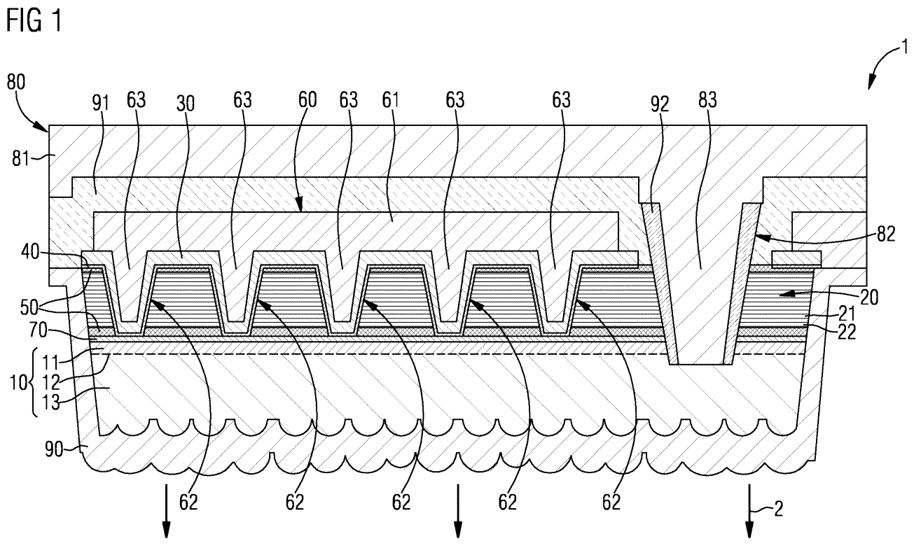

FIG. 1 illustrates a section through an optoelectronic semiconductor chip 1 in accordance with one embodiment. This optoelectronic semiconductor chip is configured for emitting electro-magnetic radiation 2 and comprises the semiconductor layer sequence 10 for this purpose. The latter comprises the first semiconductor layer 11 of a first conductivity type and also the second semiconductor layer 13 of a second conductivity type. In particular, both semiconductor layers 11 and 13 can comprise GaN. In the present case, the first semiconductor layer 11 consists of p-doped GaN and the second semiconductor layer 13 consists of n-doped GaN. Accordingly, a p-n junction is formed, which generates the electromagnetic radiation 2 when an electrical voltage is applied in the forward direction. A passivation layer 90 is arranged on the semiconductor layer sequence 10. Said passivation layer can consist of SiO₂ or comprise SiO₂, for example. Between the semiconductor layer sequence 10 and the passivation layer 90, in particular a layer of Al₂O₃ can additionally be arranged (not illustrated). The semiconductor layer sequence 10 has outcoupling structures on the side of the passivation layer in order to improve outcoupling of electro-magnetic radiation 2.

A reflective layer system 20 is arranged on the opposite side of the semiconductor layer sequence 10 with respect to the outcoupling structures. As a result, electromagnetic radiation 2 propagating in the direction of the reflective layer system can be reflected in order then to be outcoupled by means of the outcoupling structures.

The reflective layer system comprises a Bragg mirror 20 and a reflective metal layer 30. The Bragg mirror 20 has alternating first layers 21 and second layers 22, wherein the first layers 21 have a different refractive index than the second layers 22 at a wavelength of the emittable electromagnetic radiation 2. By way of example, the refractive index of the first layers 21 can be lower than the refractive index of the second layers 22 at a wavelength of the electromagnetic radiation 2. By way of example, the first layers 21 can comprise or consist of SiO₂ and the second layers can comprise or consist of Nb₂O₅. The thicknesses of these layers can be e.g. between 20 nm and 700 nm inclusive.

A dielectric layer 50, which can consist of Al₂O₃, for example, is arranged on a top side and an underside of the Bragg mirror 20. Said dielectric layer can serve as a diffusion barrier and can prevent a current flow for this purpose. Its thickness can be 5 to 90 nm, and in the present case it is e.g. 30 nm thick.

An adhesion enhancing layer 40 is arranged between the Bragg mirror 20 or the dielectric layer 50 and the reflective metal layer 30, and consists of a different material than the first layers 21 and the second layers 22 of the Bragg mirror 20 and consists of a different material than the reflective metal layer 30. The adhesion between the reflective metal layer 30 and the Bragg mirror 20 is enhanced by the adhesion enhancing layer 40. As a result, the semiconductor chip 1 becomes more robust.

Preferably, the metal layer 30 consists of silver and the adhesion enhancing layer 40 consists of ZnO and the dielectric layer 50 consists of Al203 and the adhesion enhancing layer 40 directly adjoins the metal layer 30 and the dielectric layer 50. Particularly good adhesion is attained as a result. The metal layer 30 can be 200 nm thick.

The thickness of the adhesion enhancing layer is greater than or equal to 0.5 nm and less than or equal to 5 nm. The adhesion enhancing layer can be continuous or can have interruptions.

As mentioned above, a current has to be impressed into the Semiconductor layer sequence 10 in order that the active region 12 generates the electromagnetic radiation 2. For this purpose, the semiconductor chip 1 has a plurality of first contacting cutouts 62 extending through the Bragg mirror 20. Moreover, the semiconductor chip 1 comprises a first current impressing element 60. The current impressing element 60 in turn comprises a first current impressing layer 61 and a plurality of first contacting fingers 63 monolithically connected to the first current impressing layer 61.

The first contacting fingers 63 extend into the first contacting cutouts 62 in such a way that there is a first electrically conductive connection between the first semiconductor layer 11 and the first contacting fingers 63 of the first current impressing element 60, and said first electrically conductive connection extends via the first contacting fingers 63 along the first contacting cutouts 62 and additionally extends via the first current impressing layer 61. As evident from the figure, the first electrically conductive connection extends through the adhesion enhancing layer 40 and the metal layer 30.

The current impressing layer 61 and the contacting fingers 63 can comprise the same material, e.g. gold.

The optoelectronic semiconductor chip 1 additionally comprises an electrically conductive current distribution layer 70. The first electrically conductive connection extends through the current distribution layer 70. The first contacting fingers 63 can make contact with the first semiconductor layer 11 only regionally. The additional current distribution layer 70 makes it possible to transport the current from the first contacting fingers 63 into the area of the semiconductor layer 11 in order thereby to homogenize the emission of the electromagnetic radiation 2. Without the current distribution layer 70, current impressing into the first semiconductor layer would take place only in the region of the contacting fingers 63. The current distribution layer 70 homogenizes the current impressing and thereby homogenizes a lateral intensity profile of the emitted electromagnetic radiation 2.

For the purpose of impressing current into the second semiconductor layer 13, the optoelectronic semiconductor chip 1 furthermore has a plurality of second contacting cutouts 82, only one of which is depicted. These extend not only through the Bragg mirror 20 but also through the first semiconductor layer 11. Moreover, they also extend through the metal layer 30 and the adhesion enhancing layer 40 and the current distribution layer 70. A second current impressing element 80 is arranged in the second contacting cutouts 82. Said second current impressing element comprises a second current impressing layer 81 and second contacting fingers 83 monolithically connected thereto. The second contacting fingers 83 extend into the second contacting cutout 82, such that there is a second electrically conductive connection between the second contacting finger 83 and the second semiconductor layer 13.

The second electrically conductive connection accordingly extends via the second contacting finger 83 along the second contacting cutout 82 and via the second current impressing layer 81. An insulation layer 92 is arranged between the second contacting finger 83 and the edge of the second contacting cutout 82. Said insulation layer can consist of SiO₂ or comprise SiO₂, for example. The second current impressing element 80 can comprise e.g. a solder material, for example AuSn or NiSn.

Advantageously, an insulation layer 91 is likewise arranged between the two current impressing elements 60 and 80. Said insulation layer can consist of SiO₂ or comprise SiO₂, for example.

In accordance with one variant, by means of bonding islands (not illustrated), a voltage can be applied to the two current impressing layers 81 and 82 in order to generate the electromagnetic radiation 2. In accordance with one variant, a carrier can be arranged at the second current impressing layer 81, which carrier can consist of silicon, for example.

Besides the layers illustrated, the optoelectronic semiconductor chip 1 can comprise even further layers.

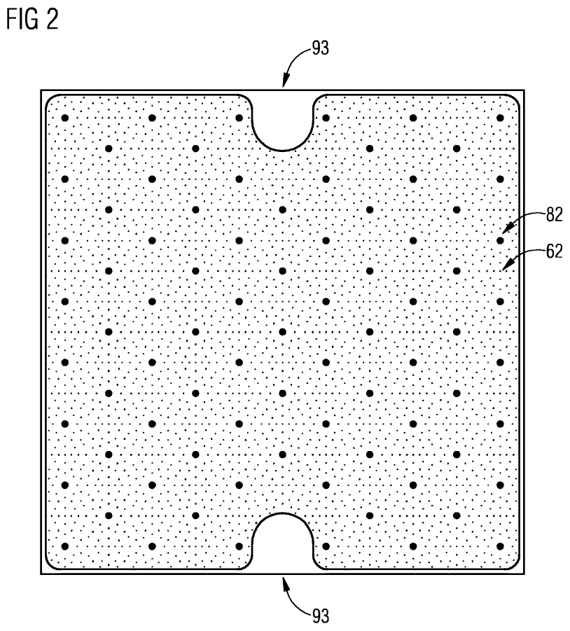

FIG. 2 illustrates the optoelectronic semiconductor chip 1 in a sectional illustration in plan view. This reveals the first 62 and the second contacting cutouts 82 and also optional bonding islands 93. For the sake of simplified illustration, FIG. illustrates fewer contacting elements than FIG. 2.

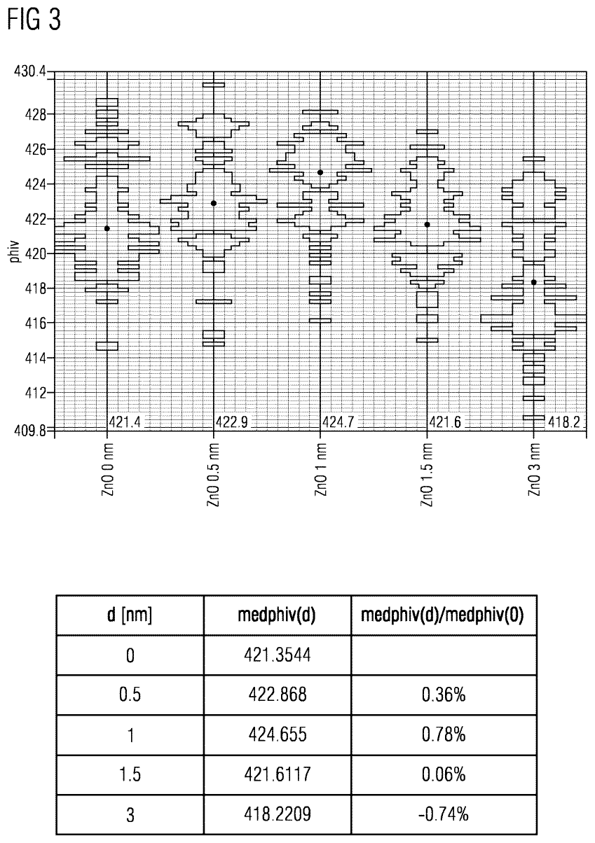

The adhesion enhancing layer 40 makes it possible to improve not only the stability of the optoelectronic semiconductor chip 1 but also the efficiency thereof. In this context, in FIG. 3, the experimentally determined luminous flux phiv(d) (arbitrary units) is plotted for five groups of optoelectronic semiconductor chips in which the thickness d of the adhesion enhancing layer 40 composed of ZnO is different (group 1: d=0 nm, group 2: d=0.5 nm, group 3: d=1 nm, group 4: d=1.5 nm, group 5: d=3 nm). The width of the bars here indicates the number of chips having the respective efficiency, and the dot indicates the median value.

The median values medphiv (d) of the luminous flux for the abovementioned layer thicknesses of the ZnO adhesion enhancing layer 40 are additionally presented in a table and compared with the median value for a layer thickness of 0 nm (no adhesion enhancing layer). Accordingly, the efficiency in terms of the median has increased by 0. 36% for a ZnO adhesion enhancing layer having a thickness, by 0. 78% for 1 nm and by 0.06% for 1.5 nm, whereas it decreases for larger layer thicknesses. Overall, accordingly, layer thicknesses of from 0.5 nm to 5 nm inclusive are preferred and layer thicknesses of from 1 nm to 3 nm inclusive are particularly preferred.

### LIST OF REFERENCE SIGNS

1 Optoelectronic semiconductor chip
2 Electromagnetic radiation
10 Semiconductor layer sequence
11 First semiconductor layer
12 Active region
13 Second semiconductor layer
20 Bragg mirror
21 First layer
22 Second layer
30 Reflective metal layer
40 Adhesion enhancing layer
50 Dielectric layer
60 First current impressing element
61 First current impressing layer
62 First contacting cutout
63 First contacting finger
70 Current distribution layer
80 Second current impressing element
81 Second current impressing layer
82 Second contacting cutout
83 Second contacting finger
90 Passivation layer
91 Insulation layer
92 Further insulation layer
93 Bonding island

1. An optoelectronic semiconductor chip comprising:
a semiconductor layer sequence having a first semiconductor layer of a first conductivity type and a second semiconductor layer of a second conductivity type and, arranged therebetween, an active region for emitting electromagnetic radiation; and
a reflective layer system, the reflective layer system comprising:
a mirror which is reflective for the electromagnetic radiation;
a metal layer which is reflective for the electromagnetic radiation, and an adhesion enhancing layer arranged between the mirror and the metal layer,
wherein the mirror comprises a Bragg mirror, having alternating first layers and second layers, wherein the first layers have a different refractive index than the second layers and the adhesion enhancing layer consists of a different material than the first layers and the second layers, and
wherein a dielectric layer is arranged between the adhesion enhancing layer and the Bragg mirror and the adhesion enhancing layer directly adjoins the dielectric layer.

2. The optoelectronic semiconductor chip according to claim 1, wherein the adhesion enhancing layer comprises zinc oxide.

3. The optoelectronic semiconductor chip according to claim 1, wherein the adhesion enhancing layer has a thickness of greater than or equal to 0.5 nm and less than or equal to 5 nm.

4. The optoelectronic semiconductor chip according to claim 1, wherein the metal layer comprises silver.

5. The optoelectronic semiconductor chip according to claim 1, wherein the adhesion enhancing layer directly adjoins the metal layer.

6. The optoelectronic semiconductor chip according to claim 1, wherein the mirror comprises a dielectric layer, wherein the adhesion enhancing layer directly adjoins the dielectric layer.

7. The optoelectronic semiconductor chip according to claim 6, wherein the dielectric layer comprises Al₂O₃.

8. The optoelectronic semiconductor chip according to claim 1, wherein the dielectric layer directly adjoins one of the first layers or one of the second layers

9. The optoelectronic semiconductor chip according to claim 1, further comprising:
a plurality of first contacting cutouts extending through the Bragg mirror;
a first electrically conductive current impressing element arranged on a side of the reflective layer system facing away from the semiconductor layer sequence, said current impressing element extending into the contacting cutouts, such that
there is a first electrically conductive connection between the first semiconductor layer and the first current impressing element and it extends via the first current impressing element along the first contacting cutouts.

10. The optoelectronic semiconductor chip according to claim 9, wherein the first current impressing element comprises a current impressing layer and also first contacting fingers monolithically connected to the current impressing layer, which extend into the first contacting cutouts, such that the first electrically conductive connection extends along the first contacting cutouts via the first contacting fingers.

11. The optoelectronic semiconductor chip according to claim 9, further comprising an electrically conductive current distribution layer, which is arranged between the semiconductor layer sequence and the reflective layer system and is transparent to the electromagnetic radiation, wherein the first electrically conductive connection extends through the transparent current distribution layer.

12. The optoelectronic semiconductor chip according to claim 11, wherein in the first contacting cutouts the adhesion enhancing layer and the metal layer extend between the current distribution layer and the first current impressing element, such that the electrically conductive connection extends through the adhesion promoting layer and the metal layer.

13. The optoelectronic semiconductor chip according to a claim 11, wherein parts of the current distribution layer are arranged between the first semiconductor layer and the Bragg mirror.

14. The optoelectronic semiconductor chip according to claim 1, further comprising at least one second contacting cutout extending through the Bragg mirror and the first semiconductor layer, and also a second electrically conductive current impressing element extending into the second contacting cutout, such that there is a second electrically conductive connection between the second semiconductor layer and the second current impressing element and it extends via the second current impressing element along the second contacting cutouts.

15. The optoelectronic semiconductor chip according to claim 1, wherein the reflective layer system is arranged on a side of the first semiconductor layer and a surface of the first semiconductor layer is planar.

16. The optoelectronic semiconductor chip according to claim 1, wherein the first semiconductor layer and the second semiconductor layer comprise contain GaN.
